(19) United States
(12) Patent Application Publication
(10) Pub. No.: US 2026/0129791 A1
(43) Pub. Date: May 7, 2026

(54) COOLING SYSTEM AND METHOD OF FAN CONTROL

(71) Applicant: IN WIN DEVELOPMENT INC., Taoyuan City (TW)

(72) Inventor: Wen-Hsien LAI, Taoyuan City (TW)

(21) Appl. No.: 19/057,317

(22) Filed: Feb. 19, 2025

(30) Foreign Application Priority Data
Nov. 5, 2024 (TW) 113142359

(51) Int. Cl. H05K 7/20

(52) U.S. Cl. CPC H05K 7/20209

(57) ABSTRACT

A method of fan control is to be implemented by a main controller, and a fan controller electrically connected to the main controller to drive a plurality of fans. The method includes: by the main controller, generating a plurality of fan control signals and transmitting, using time-division multiplexing (TDM), a TDM control signal that includes the fan control signals to the fan controller, the fan control signals corresponding respectively to the fans and being in a form of pulse-width modulation (PWM) signals; by the fan controller, in response to receipt of the TDM control signal, demultiplexing the TDM control signal to obtain the fan control signals, and generating a plurality of driving signals based respectively on the fan control signals, the driving signals being in the form of PWM signals; and by the fan controller, transmitting the driving signals respectively to the fans to drive the fans to rotate accordingly.

### CROSS-REFERENCE TO RELATED APPLICATION

This application claims priority to Taiwanese Invention Patent Application No. 113142359, filed on Nov. 5, 2024, the entire disclosure of which is incorporated by reference herein.

### FIELD

The disclosure relates to a cooling system and a method of fan control, and more particularly to a cooling system with multiple fans and a method for controlling multiple fans.

### BACKGROUND

In recent years, as the operating speed and performance of central processing units (CPUs) significantly advance, the amount of waste heat generated during operations of the CPUs rises. Modern CPUs heavily rely on conventional cooling systems to dissipate the waste heat, ensuring that the CPUs operate within a permissible temperature range. Additionally, components within a computer chassis, such as graphics cards, memory, and hard drives, also generate waste heat, and are increasing in number. Therefore, installing the conventional cooling systems within the computer chassis has become a common approach to achieving heat dissipation.

Referring to FIG. 1, a conventional cooling system 900 is installed in a computer (not shown), and includes a motherboard 91, a fan hub 92, and a plurality of fans 93 that are electrically connected to the fan hub 92. The fans 93 are mounted in different areas of the computer. The motherboard 91 outputs a driving signal to the fans 93 through the fan hub 92 to drive the fans 93 to rotate at the same speed according to the driving signal.

However, each area of the computer has a different temperature rise condition, but the motherboard 91 can only output the driving signal that controls all the fans 93 to rotate at the same time and at the same speed. Therefore, the conventional cooling system 900 is unable to adjust rotating speeds of the fans 93 separately based on the temperature rise conditions respectively of different areas of the computer, which may cause a waste of power.

### SUMMARY

Therefore, an object of the disclosure is to provide a method of fan control and a cooling system that can alleviate at least one of the drawbacks of the prior art.

According to an aspect of the disclosure, the method of fan control is to be implemented by a main controller, and a fan controller that is electrically connected to the main controller to drive a plurality of fans. The fans are electrically connected to the fan controller. The method includes: by the main controller, generating a plurality of fan control signals and transmitting, using time-division multiplexing (TDM), a TDM control signal that includes the fan control signals to the fan controller, the fan control signals corresponding respectively to the fans and being in a form of pulse-width modulation (PWM) signals; by the fan controller, in response to receipt of the TDM control signal, demultiplexing the TDM control signal thus received to obtain the fan control signals, and generating a plurality of driving signals based respectively on the fan control signals, the driving signals being in the form of PWM signals; and by the fan controller, transmitting the plurality of driving signals respectively to the fans to drive the fans to rotate accordingly.

According to another aspect of the disclosure, the cooling system includes a main controller, a fan controller and a plurality of fans. The fan controller is electrically connected to the main controller. The fans are electrically connected to the fan controller. The main controller is configured to generate a plurality of fan control signals, and transmit, using TDM, a TDM control signal that includes the fan control signals to the fan controller. The fan control signals correspond respectively to the fans and are in a form of PWM signals. The fan controller is configured to, in response to receipt of the TDM control signal, demultiplex the TDM control signal thus received to obtain the fan control signals, and generate a plurality of driving signals based respectively on the fan control signals, where the driving signals are in the form of PWM signals. The fan controller is further configured to transmit the driving signals respectively to the fans to drive the fans to rotate accordingly.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic diagram of a conventional cooling system.

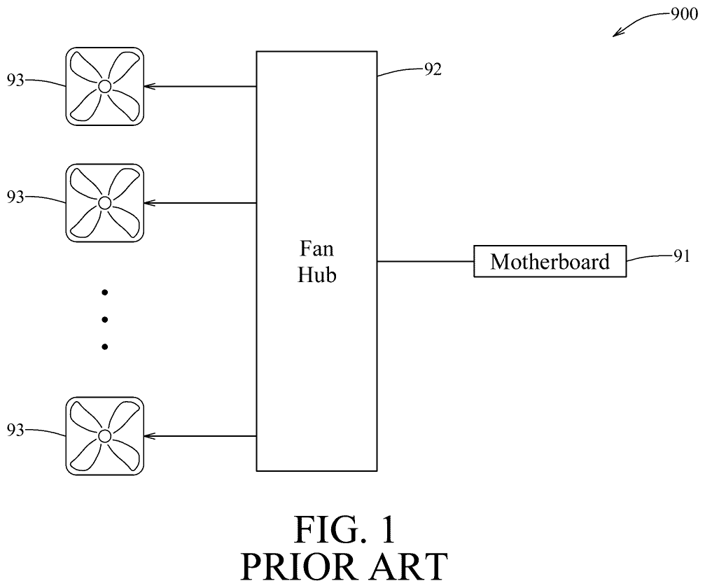

FIG. 2 is a schematic diagram of a cooling system according to an embodiment of the disclosure.

FIG. 3 is a signal timing diagram illustrating a frame of a time-division multiplexing (TDM) control signal within a signal cycle thereof.

FIG. 4 is a flow chart illustrating a fan driving procedure of an embodiment of the disclosure.

FIG. 5 is a signal timing diagram illustrating a frame of a TDM speed signal within a signal cycle thereof.

FIG. 6 is a flow chart illustrating a fan speed detection procedure of an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

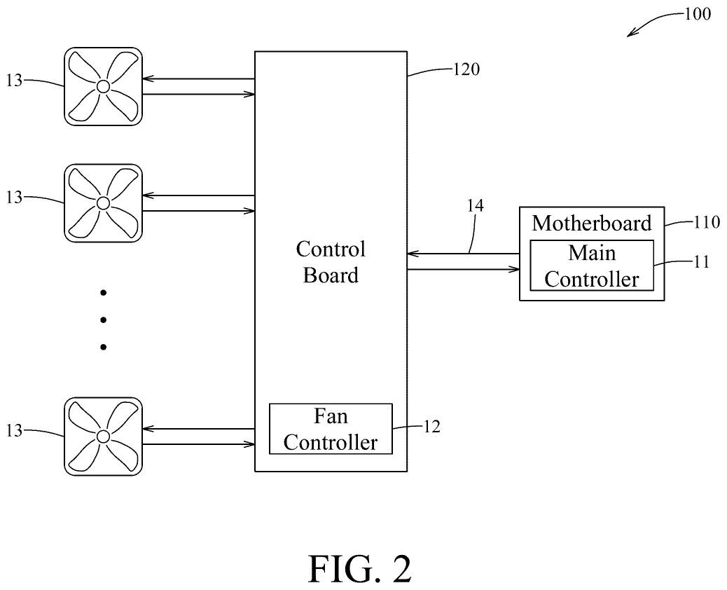

Referring to FIG. 2, a cooling system 100 according to an embodiment of the present disclosure includes a main controller 11, a fan controller 12 electrically connected to the main controller 11, and a plurality of fans 13 electrically connected to the fan controller 12. In some embodiments, the fans 13 may be arranged in an array within a server rack or mounted in a computer chassis respectively at locations that correspond to different electronic components for heat dissipation, but the disclosure is not limited in this respect. The main controller 11 in cooperation with the fan controller 12, performs a method of fan control to control operations of the fans 13. The method of fan control includes a fan driving procedure for driving the fans 13 to rotate, and a fan speed detection procedure for detecting rotational speeds of the fans 13.

The main controller 11 and/or the fan controller 12 may include, but are/is not limited to, at least one or more of a microcontroller, a controller integrated circuit (IC), a microprocessor, a digital signal processor (DSP), a complex programmable logic device (CPLD), a field programmable gate array (FPGA), and an application special integrated circuit (ASIC). Each of the fans 13 may be exemplified as a brushless DC (BLDC) motor fan, but the disclosure is not limited in this respect.

The cooling system 100 of this disclosure may perform the method of fan control by using programming or scripting languages such as C, C++, Java, x86 assembly language and Python, and by implementing various algorithms through a combination of instructions, data structures, procedures, routines, or other programming configurations, but the disclosure is not limited in this respect. In some embodiments, the main controller 11 and the fan controller 12 may be disposed respectively on a motherboard 110 and a control board 120. In some embodiments, the control board 120 and the motherboard 110 are two separate boards, and the control board 120 is electrically connected to the motherboard 110 via a connecting interface 14, such as wires, cables and/or slots. Each of the main controller 11 and the fan controller 12 may be configured to execute instructions to implement the abovementioned algorithms, in order to perform operations within the method of fan control that are to be performed respectively by the main controller 11 and the fan controller 12.

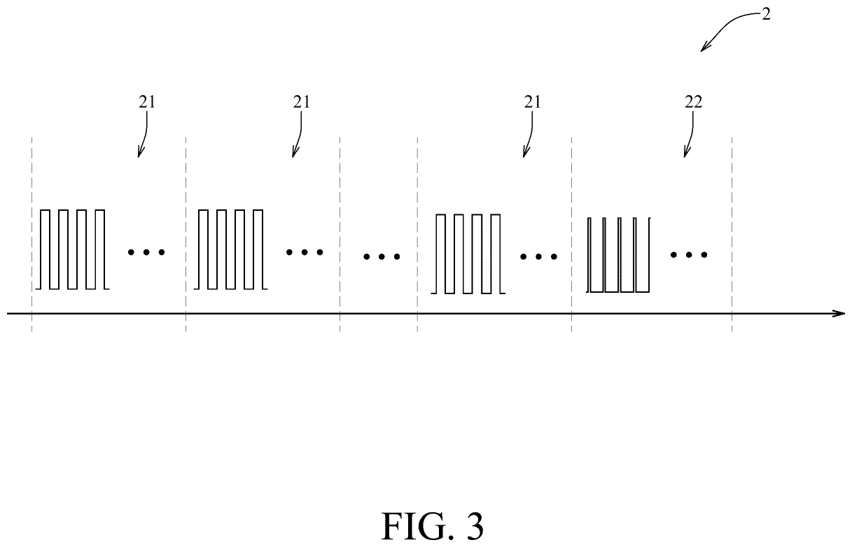

Referring to FIGS. 2 and 3, an example of a frame of a time-division multiplexing (TDM) control signal 2 that corresponds to a signal cycle of the TDM control signal 2 when the cooling system 100 of this disclosure is performing the fan driving procedure is presented. Within the signal cycle of the TDM control signal 2, the TDM control signal 2 includes a plurality of fan control signals 21 and a control-end signal 22. A time length of each of the fan control signals 21 and a time length of the control-end signal 22 are identical. Furthermore, a number of the fan control signals 21 is the same as a number of the fans 13. In this embodiment, the time length of each of the fan control signals 21 is five seconds and the time length of the control-end signal 22 is also five seconds.

The fan control signals 21 correspond respectively to the fans 13, and are in a form of pulse-width modulation (PWM) signals. In this embodiment, a duty cycle of each of the fan control signals 21 is greater than twenty percent. During transmission of the TDM control signal 2, the fan control signals 21 are first sequentially transmitted, and the control-end signal 22 follows the fan control signals 21. The control-end signal 22 is in a form of a PWM signal and has a duty cycle of less than twenty percent. The duty cycle of the control-end signal 22 is set to be less than twenty percent to distinguish the control-end signal 22 from the fan control signals 21, and to indicate an end of the signal cycle of the TDM control signal 2.

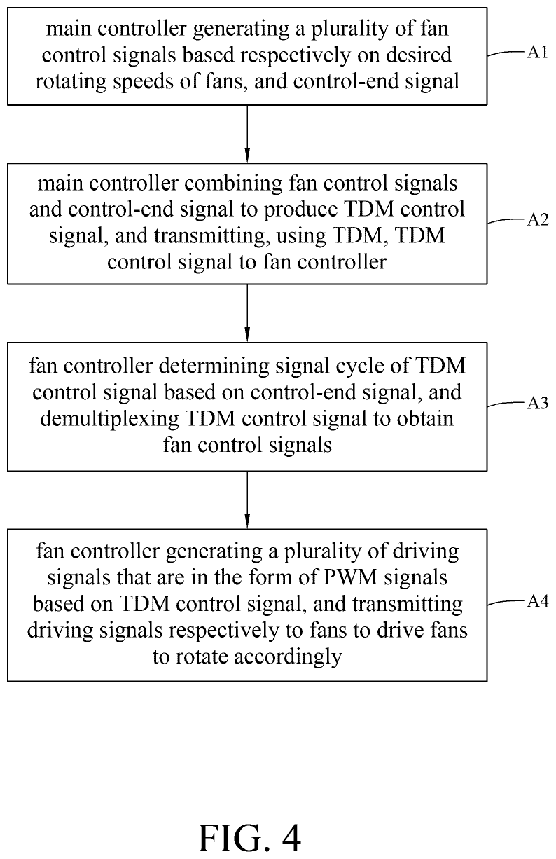

Referring to FIG. 4, the fan driving procedure includes steps A1 to A4.

Referring further to FIGS. 2 and 3, in step A1, the main controller 11 generates a plurality of fan control signals 21 based respectively on desired rotating speeds of the fans 13, and a control-end signal 22. In some embodiments, the desired rotating speeds respectively of the fans 13 may be set by a user through an interface (not shown), or by the main controller 11 according to, for example, current temperatures respectively of the different electronic components detected respectively by sensors. That is to say, the desired rotating speeds respectively for the fans 13 may be different from each other, and the main controller 11 may generate the fan control signals 21 with different duty cycles for respectively controlling the fans 13 to rotate at different rotating speeds based respectively on the desired rotating speeds of the fans 13. Since a way of setting the duty cycles of the fan control signals 21 based respectively on the desired rotational speeds is well known in the art, further descriptions thereof will be omitted for the sake of brevity.

In step A2, the main controller 11 combines the fan control signals 21 and the control-end signal 22 to produce a TDM control signal 2, and transmits, using TDM, the TDM control signal 2 to the fan controller 12. In some embodiments, the TDM control signal 2 has a plurality of first time slots with equal time lengths. Referring to FIG. 3, when the main controller 11 transmits the TDM control signal 2 to the fan controller 12, the main controller 11, within a signal cycle of the TDM control signal 2, sequentially transmits the fan control signals 21 in earlier ones of the first time slots, and transmits the control-end signal 22 in a last one of the first time slots.

In step A3, the fan controller 12, in response to receipt of the TDM control signal 2, determines the signal cycle of the TDM control signal 2 thus received based on the control-end signal 22, and demultiplexes the TDM control signal 2 to obtain the fan control signals 21.

In step A4, the fan controller 12 generates a plurality of driving signals based respectively on the fan control signals 21 obtained from the TDM control signal 2. The driving signals are in the form of PWM signals. The fan controller 12 transmits the driving signals respectively to the fans 13 to drive the fans 13 to rotate accordingly. Generally, a duty cycle of a driving signal is required to be higher than twenty percent to drive a fan to rotate. In some embodiments, for each of the driving signals generated by the fan controller 12, the duty cycle of the driving signal is the same as the duty cycle of the respective one of the fan control signals 21. That is to say, in those embodiments, the duty cycle of each of the driving signals generated by the fan controller 12 is also more than twenty percent. Additionally, with respect to each of the driving signals, the duty cycle of the driving signal, which is continuously transmitted by the fan controller 12 to the respective one of the fans 13, remains the same until the fan controller 12 obtains a new fan control signal 21 (e.g., when the fan controller 12 receives another frame of the TDM control signal 2 from the main controller 11 during a next signal cycle of the TDM control signal 2), and the fan controller 12 generates another driving signal based on the new fan control signal 21.

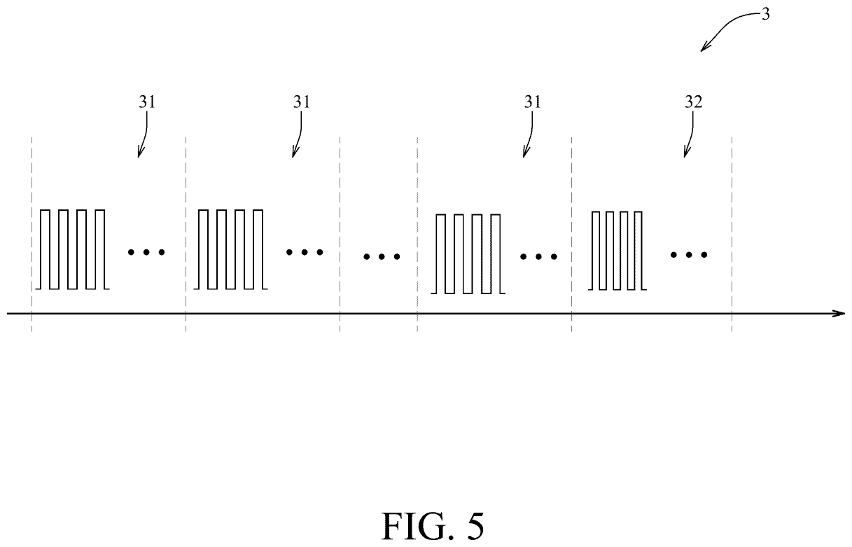

Referring to FIGS. 2 and 5, an example of a frame of a TDM speed signal 3 that corresponds to a signal cycle of the TDM speed signal 3 when the cooling system 100 of this disclosure is performing the fan speed detection procedure is presented. Within the signal cycle of the TDM speed signal 3, the TDM speed signal 3 includes a plurality of fan speed signals 31 and a speed-end signal 32. A time length of each of the fan speed signals 31 and a time length of the speed-end signal 32 are identical. Furthermore, a number of the fan speed signals 31 is the same as the number of the fans 13. In this embodiment, the time length of each of the fan speed signals 31 is five seconds and the time length of the speed-end signal 32 is also five seconds.

The fan speed signals 31 correspond respectively to the fans 13, and are in a form of pulse wave signals. During transmission of the TDM speed signal 3, the fan speed signals 31 are first sequentially transmitted, and the speed-end signal 32 follows the fan speed signals 31. The speed-end signal 32 is also in a form of a pulse wave signal. In this embodiment, each of the fan speed signals 31 and the speed-end signal 32 are in a form of square wave signals.

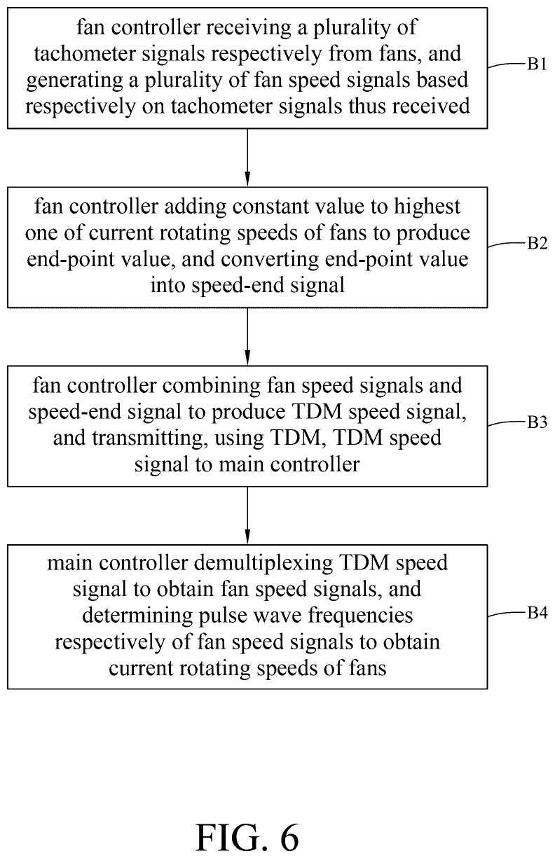

Referring to FIG. 6, the fan speed detection procedure includes steps B1 to B4.

Referring to FIGS. 2, 5 and 6, in step B1, the fan controller 12 receives from the fans 13 a plurality of tachometer signals, respectively, and the tachometer signals correspond respectively to current rotating speeds of the fans 13. The fan controller 12 then generates a plurality of fan speed signals 31 based respectively on the tachometer signals thus received. Specifically, the fan controller 12 determines the current rotating speeds of the fans 13 based respectively on the tachometer signals thus received, and generates the fan speed signals 31 based respectively on the current rotating speeds of the fans 13, wherein for each of the fans 13, the higher the current rotating speed of the fan 13, the higher the frequency of the fan speed signal 31 that is correspondingly generated. In some embodiments, each of the fans 13 includes a tachometer (not shown) that detects the current rotating speed of the fan 13 and outputs the respective one of the tachometer signals. For example, when one of the fans 13 is rotating and completes one resolution, the tachometer of said one of the fans 13 correspondingly outputs two square waves as the tachometer signal of said one of the fans 13. A way of determining the current rotating speeds of the fans 13 by respectively analyzing frequencies of the tachometer signals is well-known in the art and will not be further described for the sake of brevity.

In step B2, the fan controller 12 adds a constant value to a highest one of the current rotating speeds of the fans 13 thus determined to produce an end-point value, and converts the end-point value into a speed-end signal 32. In this embodiment, the constant value is 120 (i.e., a rotation speed of 120 per minute that corresponds to a frequency of 2 Hz). In other embodiments, the constant value may be 180 (i.e., a rotation speed of 180 per minute that corresponds to a frequency of 3 Hz).

In step B3, the fan controller 12 combines the fan speed signals 31 and the speed-end signal 32 to produce a TDM speed signal 3, and transmits, using TDM, the TDM speed signal 3 to the main controller 11. Specifically, the TDM speed signal 3 has a plurality of second time slots with equal time lengths. Referring to FIG. 5, when the fan controller 12 transmits the TDM speed signal 3 to the main controller 11, the fan controller 12, within a signal cycle of the TDM speed signal 3, sequentially transmits the fan speed signals 31 in earlier ones of the second time slots, and transmits the speed-end signal 32 in a last one of the second time slots.

In step B4, the main controller 11, in response to receipt of the TDM speed signal 3, demultiplexes the TDM speed signal 3 to obtain the fan speed signals 31, and determines pulse wave frequencies respectively of the fan speed signals 31 to obtain the current rotating speeds of the fans 13. In one embodiment, the main controller 11 determines the signal cycle of the TDM speed signal 3 thus received based on the speed-end signal 32, and the signal cycle may be used to facilitate demultiplexing the TDM speed signal 3.

In summary, the main controller 11 transmits the TDM control signal 2 to the fan controller 12 using TDM, the fan controller 12 generates the driving signals based on the TDM control signal 2 thus received, and the fan controller 12 then transmits the driving signals respectively to the fans 13 to drive the fans 13 to rotate accordingly. Additionally, the fans 13 generate the tachometer signals based respectively on the current rotating speeds of the fans 13, and transmit the tachometer signals to the fan controller 12. The fan controller 12 then generates the TDM speed signal 3 based on the tachometer signals thus received, and transmits the TDM speed signal 3 to the main controller 11 to feedback the current rotating speeds of the fans 13 to the main controller 11. By virtue of the aforementioned arrangement, the cooling system 100 of this disclosure is able to transmit the driving signals with different duty cycles respectively to the fans 13 to respectively drive the fans 13 to rotate at different rotational speeds to accommodate different needs for heat dissipation, thereby improving power utilization efficiency.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method of fan control, the method to be implemented by a main controller and a fan controller that is electrically connected to the main controller to drive a plurality of fans, the plurality of fans being electrically connected to the fan controller, the method comprising:
by the main controller, generating a plurality of fan control signals and transmitting, using time-division multiplexing (TDM), a TDM control signal that includes the plurality of fan control signals to the fan controller, the plurality of fan control signals corresponding respectively to the plurality of fans and being in a form of pulse-width modulation (PWM) signals;
by the fan controller, in response to receipt of the TDM control signal, demultiplexing the TDM control signal thus received to obtain the plurality of fan control signals, and generating a plurality of driving signals based respectively on the plurality of fan control signals, the plurality of driving signals being in the form of PWM signals; and
by the fan controller, transmitting the plurality of driving signals respectively to the plurality of fans to drive the plurality of fans to rotate accordingly.

2. The method as claimed in claim 1, wherein transmitting the TDM control signal to the fan controller includes the main controller, within a signal cycle of the TDM control signal, sequentially transmitting the plurality of fan control signals and a control-end signal that follows the plurality of fan control signals, the control-end signal being in a form of a PWM signal and having a duty cycle of less than twenty percent; and
wherein demultiplexing the TDM control signal includes the fan controller determining the signal cycle of the TDM control signal based on the control-end signal in order to obtain the plurality of fan control signals.

3. The method as claimed in claim 1, further comprising:
by the fan controller, receiving a plurality of tachometer signals respectively from the plurality of fans, the plurality of tachometer signals corresponding respectively to current rotating speeds of the plurality of fans; and
by the fan controller, generating a plurality of fan speed signals, which are in a form of pulse wave signals, based respectively on the plurality of tachometer signals thus received, and transmitting, using the TDM, a TDM speed signal that includes the plurality of fan speed signals to the main controller.

4. The method as claimed in claim 3, further comprising:
by the main controller, in response to receipt of the TDM speed signal from the fan controller, demultiplexing the TDM speed signal to obtain the plurality of fan speed signals, and determining pulse wave frequencies respectively of the plurality of fan speed signals to obtain the current rotating speeds of the plurality of fans.

5. The method as claimed in claim 3, wherein transmitting the TDM speed signal to the main controller includes the fan controller determining the current rotating speeds of the plurality of fans based respectively on the plurality of tachometer signals, adding a constant value to a highest one of the current rotating speeds of the plurality of fans thus determined to produce an end-point value, converting the end-point value into a speed-end signal that is in a form of a pulse wave signal, and within a signal cycle of the TDM speed signal, sequentially transmitting the plurality of fan speed signals and the speed-end signal that follows the plurality of fan speed signals to the main controller.

6. The method as claimed in claim 3, wherein in generating the plurality of fan speed signals, for each of the plurality of fans, when the current rotating speed of the fan becomes higher, a frequency of the fan speed signal that is correspondingly generated becomes higher.

7. The method as claimed in claim 1, wherein in generating the plurality of driving signals based respectively on the plurality of fan control signals, each of the plurality of driving signals has a duty cycle that is same as a duty cycle of the respective one of the plurality of fan control signals.

8. A cooling system comprising:
a main controller;
a fan controller electrically connected to said main controller; and
a plurality of fans electrically connected to said fan controller,
wherein said main controller is configured to generate a plurality of fan control signals, and transmit, using time-division multiplexing (TDM), a TDM control signal that includes the plurality of fan control signals to said fan controller, the plurality of fan control signals corresponding respectively to said plurality of fans and being in a form of PWM signals,
wherein said fan controller is configured to, in response to receipt of the TDM control signal, demultiplex the TDM control signal thus received to obtain the plurality of fan control signals, and generate a plurality of driving signals based respectively on the plurality of fan control signals, the plurality of driving signals being in the form of PWM signals, and
wherein said fan controller is further configured to transmit the plurality of driving signals respectively to said plurality of fans to drive said plurality of fans to rotate accordingly.

9. The cooling system as claimed in claim 8, wherein said main controller is configured to, when transmitting the TDM control signal to said fan controller, within a signal cycle of the TDM control signal, sequentially transmit the plurality of fan control signals and a control-end signal that follows the plurality of fan control signals, the control-end signal being in a form of a PWM signal and having a duty cycle of less than twenty percent; and
wherein said fan controller is configured to, when demultiplexing the TDM control signal, determine the signal cycle of the TDM control signal based on the control-end signal in order to obtain the plurality of fan control signals.

10. The cooling system as claimed in claim 8, wherein said fan controller is further configured to receive respectively from said plurality of fans a plurality of tachometer signals that correspond respectively to current rotating speeds of said plurality of fans, generate a plurality of fan speed signals based respectively on the plurality of tachometer signals thus received, and transmit, using the TDM, a TDM speed signal that includes the plurality of fan speed signals to said main controller, the plurality of fan speed signals being in a form of pulse wave signals.

11. The cooling system as claimed in claim 10, wherein said main controller is further configured to, in response to receipt of the TDM speed signal from said fan controller, demultiplex the TDM speed signal to obtain the plurality of fan speed signals, and determine pulse wave frequencies respectively of the plurality of fan speed signal to obtain the current rotating speeds of said plurality of fans.

12. The cooling system as claimed in claim 10, wherein said fan controller is configured to, when transmitting the TDM speed signal to said main controller, determine the current rotating speeds of said plurality of fans based respectively on the plurality of tachometer signals, add a constant value to a highest one of the current rotating speeds of said plurality of fans thus determined to produce an end-point value, convert the end-point value into a speed-end signal that is in a form of a pulse wave signal, and within a signal cycle of the TDM speed signal, sequentially transmit the plurality of fan speed signals and the speed-end signal that follows the plurality of fan speed signals to said main controller.

13. The cooling system as claimed in claim 10, wherein for each of said plurality of fans, when the current rotating speed of said fan becomes higher, a frequency of the fan speed signal that is correspondingly generated becomes higher.

14. The cooling system as claimed in claim 8, wherein each of the plurality of driving signals has a duty cycle that is same as a duty cycle of the respective one of the plurality of fan control signals.

15. The cooling system as claimed in claim 8, further comprising a motherboard that includes said main controller, and a control board that includes said fan controller and that is electrically connected to said motherboard.
